(19) United States
(12) Patent Application Publication
(10) Pub. No.: US 2011/0266504 A1
(43) Pub. Date: Nov. 3, 2011

(54) DEPOSITION FROM IONIC LIQUIDS

(75) Inventor: Jan Fransaer, Leefdaal (BE)

(73) Assignee: KATHOLIEKE UNIVERSITEIT LEUVEN, Leuven (BE)

(21) Appl. No.: 12/673,218

(22) PCT Filed: Jul. 25, 2008
(86) PCT No.: PCT/EP2008/059783

§ 371 Date: Feb. 12, 2010

(30) Foreign Application Priority Data
Aug. 6, 2007 (GB) 0715258.0

(51) Int. Cl. B05D 5/12; C25D 5/00; H01L 21/20; H01B 1/02; H01B 1/06

(52) U.S. Cl. 252/512; 427/123; 252/500; 438/478; 205/88; 257/E21.09

(57) ABSTRACT

A method to electrodeposit or electroless deposit material onto substrates from ionic liquids in vacuum or in a protective atmosphere after exposing the ionic liquid to vacuum and the resulting material. According to the invention, dense layers, free of unwanted components, can be produced in vacuum or in a protective atmosphere after exposing the ionic liquid to vacuum.

### BACKGROUND OF THE INVENTION

1. Field of the Invention

The present invention relates in general to electrodeposition or electroless deposition methods of metals or semiconductors on substrates from ionic liquids.

2. Description of the Prior Art

The electrodeposition of metals from ionic liquids is well known and is discussed in various publications (Electrochemical aspects of ionic liquids, H. Ohno (editor), Wiley Interscience, Tokyo (2005) and references therein) and in the patent literature (U.S. Pat. No. 6,573,405, Ionic liquids, from Abbott et al., U.S. Pat. No. 7,196,221, Ionic liquids and their use, from Abbott et al., WO2006/053362 A2, Method for depositing layers from ionic liquids, from Plansee et al., WO2006/061081 A2, Electrochemical deposition of tantalum and/or copper in ionic liquids, from Welz-Biermann et al., WO2006/074523 A1, Recovery of metals, from Houchin et al.

The interest in electrodeposition and (to a lesser extent) electroless deposition from ionic liquids stems from their properties:
a wide potential window, sometimes exceeding 4 volts, which gives access to elements which cannot be electrodeposited from aqueous or organic solutions.
a high solubility for metal salts,
a high conductivity compared to non-aqueous solvents
allow to avoid water, by working with hydrophobic ionic liquids in combination with protective atmospheres (e.g. as provided inside a glove box).

Hence, ionic liquids are used or claimed for use in for example batteries, fuel cells, photovoltaic devices, electropolishing and electrodeposition processes.

Another important property of most ionic liquids is their very low vapour pressure. The low vapour pressure is advantageous from a health, safety and environmental point of view. The study of the distillation and volatility of ionic liquids has only recently been explored, e.g. Earle et al. (The distillation and volatility of ionic liquids, Nature, vol. 439, 16 Feb. 2006, 831-834, M. J. Eerie, J. M. S. S. Esperanga, M. A. Gilea, J. N. Canongia Lopez, L. P. N. Rebelo, J. W. Magee, K. R. Seddon and J. A. Widegren), J. P. Armstrong et al. (Vapourisation of ionic liquids, J. P. Armstrong, C. Hurst, R. G. Jones, P. Licence, K. R. J. Lovelock, C. J. Satterley and I. J. Villar-Garcia, Phys. Chem. Chem. Phys, vol. 9, 982-990 (2007)), Relative volatilities of ionic liquids by vacuum distillation of mixtures, J. A. Widgren, Y. M. Wang, W. A. Henderson and J. W. Magee, J. Phys. Chem. B, published on the web Jul. 7, 2007, vapor pressure and thermal stability of ionic liquid 1-butyl-3-methylimidazolium bis(trifluoromethylsulfonyl)amide, Y. U. Paulechka, Dz. H. Zaitsau, G. J. Kabo and A. A. Strechan, Thermochimica Acta, Vol. 439, pp. 158-160 (2005), Experimental vapor pressures of 1-alkyl-3-methylimidazolium bis(trifluoromethylsulfonyl)imides and a correlation scheme for estimation of vaporization enthalpies of ionic liquids, D. H. Zaitsau, G. J. Kabo, A. A. Strechan, Y. U. Paulechka, A. Tschersich, S. P. Verevkin and A. Heintz, J. Phys. Chem. A, vol 110, pp. 7303-7306 (2006).

The low volatility of ionic liquids has also led to the use of ultra-high vacuum methods such as X-ray photoelectron spectroscopy and static secondary ion mass spectrometry (SIMS) to study ionic liquids, e.g. Ionic liquids in vacuo: analysis of liquid surfaces using ultra-high-vacuum techniques, E. F. Smith, F. J. M. Rutten, I. J. Villar-Garcia, D. Briggs and P. Licence, Langmuir, vol. 22, pp. 9386-9392 (2006) and Ionic liquids in vacuo; solution-phase X-ray photoelectron spectroscopy, E. F. Smith, I. J. Villar-Garcia, D. Briggs and P. Licence). More recently, the thermal evaporation of silver in vacuum onto an ionic liquid was proposed as a basis for a lunar telescope. (Deposition of metal films on an ionic liquid as a basis for a lunar telescope, E. F. Borra, O, Seddiki, R. Angel, D. Eisenstein, P. Hickson, K. R. Seddon and S. P. Worden, Nature, vol. 447, pp. 979-981, 21 Jun. 2007

Various authors have mentioned the low vapour pressures of ionic liquids (10⁻¹¹-10⁻¹² mbar at room temperature) as an interesting property which enables experiments at temperatures upto 300° C. on a longer time scale and 400° C. on a short time scale and that the extremely low vapour pressures allow experiments under vacuum conditions.

However, thus far, the low vapour pressure (which seems to be an intrinsic property of ionic liquids) has been overlooked as an important advantage in the electrodeposition or electroless deposition from ionic liquids. We have found that the low vapour pressure of ionic liquids allows the electrodeposition or electroless deposition of material in a high-vacuum, and allows the evacuation of all gas from the atmosphere in contact with the ionic liquid prior to electrodeposition by exposing the ionic liquid to a high vacuum followed by purging with a protective gas (e.g. noble gas). This allows the electrodeposition or electroless deposition on substrates that would otherwise oxidize or hydrolyse due to contact with oxygen or water (vapour) such as tantalum, niobium or other valve metals. Besides, all metals when exposed to oxygen or water form a layer of physisorbed or chemisorbed oxygen or oxygen containing species that can be detrimental for obtaining high nucleation densities of the species to be deposited on the substrate.

The method of this invention solves one of the problems in the miniaturization of the Damascene process in which copper is electrodeposited on a diffusion barrier, often Ta or TaN. Electrodeposition of copper from an aqueous plating solution directly onto Ta is not possible as Ta will spontaneously cover itself with an oxide (or hydroxide) layer when brought in contact with air or water. This reaction layer gives rise to a substantial contact resistance and hampers the nucleation of copper onto the barrier layer. Hence, before plating, a thin copper seed layer is deposited onto the barrier layer. This seed layer is deposited by PVD, ALD or CVD methods. The conformity and the thickness of the seed layer makes it difficult to fill the sub-32 nm vias without defects by copper deposition. However, if copper is deposited from an ionic liquid in high-vacuum, the oxidation of Ta can be avoided allowing direct-on-barrier deposition. In their patent WO2006/061081 A2, Biermann, Endres and Zein El Abedin discuss the possibility to electrodeposit Ta and Cu from ionic liquids under protective atmosphere in a glove box. However, even at the low oxygen and water concentrations of a glove box (which for a very good glove box is at most 0.5 to 1 ppm of oxygen and water), the oxidation of tantalum is very fast and Ta will be covered with an oxide layer in a very short time. Only by working in a vacuum, can the oxidation of tantalum be slowed down sufficiently to enable the direct deposition of copper.

### SUMMARY OF INVENTION

This invention relates to a method to electrodeposit or electroless deposit layers comprised of metallic or semiconducting elements and/or combinations thereof onto substrates from ionic liquids in vacuum or in a protective atmosphere after exposing the ionic liquid to a vacuum and the resulting material. According to the invention, dense layers, free of unwanted components, can be produced at low temperature (preferably below 100° C.) in vacuum or in a protective atmosphere after exposing the ionic liquid to high vacuum. This technique and the resulting material are particularly suitable for the micro-electronic industry, where contamination of materials and devices is critical. More specifically, this method can be used to deposit copper directly onto Ta and Ta-based barriers without the need for a copper seed layer.

One way to directly deposit copper onto tantalum based barrier layers would involve transferring a substrate to a transfer module (in which the pressure is of the order of 10⁻⁸ Pa) through a load-lock. From the transfer module, the substrate is transferred to a deposition chamber where the deposition of the tantalum layer takes place (e.g. by means of Physical Vapor Deposition (PVD) at a base pressure of the order of 10⁻⁸ Pa). After the deposition of the tantalum layer, the substrate is transferred back to the transfer module and subsequently transferred to a second deposition chamber (pressure below 10⁻⁴ Pa) where the substrate is brought into contact with the ionic liquid and the deposition of metallic or semiconducting species from the ionic liquid onto the substrate takes place. Prior to this deposition process, the ionic liquid is subjected to a vacuum step (with a pressure below 10⁻⁴ Pa) in order to remove oxygen and water, thus avoiding the oxidation of the tantalum.

An ionic liquid is a molten salt that is composed solely of anions and cations. Some ionic liquids are molten below 100° C. and some are even liquid at room temperature. These last salts are sometimes called room temperature ionic liquids (RTIL). In principle, an enormous range of ionic liquids can be prepared based on combinations of various cations and anions.

Typical cations that may be used in ionic liquids include: tetraalkylammonium, tetraalkylphosphonium, trialkylsulfonium, N,N-dialkylimidazolium, N,N-dialkyl-pyrrolidinium, tetraalkylphosphonium, N-alkylpyridinium, N,N-dialkyl-piperidinium. The substituent groups attached to the nitrogen or phosphorous atom may be the same or different aliphatic or aromatic groups, or combinations of these groups. Examples of these groups include alkyl, alkenyl, alkynyl and aryl groups and heteroaryl groups in which the hetero atoms is selected from N, S, O, P, Si and Se. The substituent groups may themselves be substituted by such groups as halogens and/or other functional groups. Preferred functional groups include F and CN.Anion components of ionic liquids are typically smaller species, and include by way of example Cl⁻, BF₄⁻, PF₆⁻, NO₃⁻, alkylsulfonate (RSO₃⁻) acetate, trifluoroacetate, substituted sulfonates (e.g. trifluoroethanesulfonate), bromide, tetracyanoborate, alkylsulfate, bis(trifluoromethylsulfonyl)imide, bis(trifluoromethyl)imide and dicyanamide anions. Thiols (RS⁻), dithiocarbamates (RNCS₂⁻) and xanthates (ROCS₂⁻), in which the groups R are as defined above for the cationic components, are also believed to be useful in the formation of suitable ionic liquids.

| | | |
|---|---|---|
| 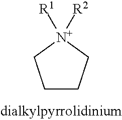 | 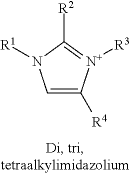 | 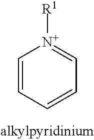 |
| 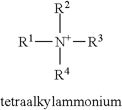 | 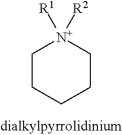 | 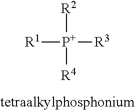 |
| 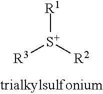 | | |

Any suitable source material capable of depositing the desired species onto the substrate by electrolytic or electroless deposition can be used. By “species” in this context is meant metal, inorganic oxide, including metal oxide, non-oxide semiconductor/conductor or organic polymer. Suitable source materials will be apparent to the person skilled in the art.

One or more source materials may be included in the mixture in order to deposit one or more species simultaneously. Different species may be deposited simultaneously from the same mixture. Alternatively, different species may be deposited sequentially into layers from the same mixture, by varying the potential or current density such that one or another species is preferentially deposited according to the potential selected.

Suitable metals include for example Group IIB, IIIA-VIA metals from the periodic table, in particular zinc, cadmium, aluminium, gallium, indium, thallium, tin, lead, antimony and bismuth, first, second and third row transition metals, in particular platinum, palladium, gold, rhodium, ruthenium, silver, iridium, osmium, nickel cobalt, copper, iron, chromium and manganese, and most preferably copper, and lanthanide and actinide metals, for example samarium, neodymium, gadolinium and uranium.

The ionic liquid may or may not contain additives that improve the solubility of the source material.

The ionic liquid may or may not contain additives that improve the nucleation density of the depositing material.

The metals may be deposited from their salts as single metals or as alloys.

The pressure to which the ionic liquid is exposed during plating or before plating is comprised between 100 and 10⁻⁸ Pa and preferably below 10⁻⁴ Pa. The temperature during deposition is comprised between 0° C. and 350° C. and preferably between 20° C. and 200° C.

The concentration of metal ions to be deposited from the ionic liquid is comprised between 10⁻⁵ to 10 mol/l, and preferably between 10⁻³ and 1 mol/l.

In case of electrodeposition, the deposition takes place either under controlled current or controlled potential. The applied current densities lie between 10⁻⁷ and 10 A/dm², depending on the concentration of the reducible metal ion and stirring rate of the ionic liquid. The electrolytic deposition can take place either using a two-electrode or a three-electrode configuration. The material of the anode can be any metal or material that is sufficiently conductive and does not generate products that interfere with the deposition process at the cathode. In case of copper deposition a copper anode can be used, but an inert anode made of Pt is also possible.

In case of electroless deposition, a suitable reducing agent, capable of reducing the ions to be deposited from the ionic liquid is added to the ionic liquid. Possible reducing agents are LiBH₄, KBH₄, NaBH₄, N₂H₄, HCHO, Ti₃₊ ions, where the last three reducing agents are preferred if the deposit should not contain boron.

The deposited material and coatings are particularly suitable for the manufacturing of interconnects in the micro-electronic industry, where the presence of oxygen or water hampers the direct deposition on Ta and Ta-based barriers.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description. It is to be understood that both the foregoing general description and the following detailed description are exemplary and explanatory only and are not restrictive of the invention, as claimed.

### BRIEF DESCRIPTION OF DRAWINGS

FIG. 1 displays a SEM picture of surface of a copper layer deposited on a gold TEM grid in high-vacuum.

FIG. 2 shows the EDX spectrum of surface of a copper layer deposited on a Au TEM grid in high-vacuum.

FIG. 3 displays a SEM picture of surface of a cobalt layer deposited on a copper TEM grid in low-vacuum.

FIG. 4 shows the EDX spectrum of surface of a cobalt layer deposited on a copper TEM grid in low-vacuum.

FIG. 5 displays a SEM picture of surface of a cobalt layer deposited on a copper TEM grid in high-vacuum.

FIG. 6 shows the EDX spectrum of surface of a cobalt layer deposited on a copper TEM grid in high-vacuum.

FIG. 7 displays a SEM picture of surface of a copper layer deposited on a gold TEM grid in high-vacuum.

FIG. 8 shows the EDX spectrum of surface of a copper layer deposited on a gold TEM grid in high-vacuum.

The following examples do not limit the invention. Instead, the scope of the invention is defined by the appended claims and equivalents thereof. It will be apparent to those skilled in the art that various modifications and variations can be made in construction of the system and method and more particularly in the deposition of material from ionic liquids in a vacuum or in a protective atmosphere after exposing the ionic liquid to a vacuum or in the use of this method for depositing material without departing from the scope or spirit of the invention.

Other embodiments of the invention will be apparent to those skilled in the art from consideration of the specification and practice of the invention disclosed herein. It is intended that the specification and examples be considered as exemplary only.

### EXAMPLE 1

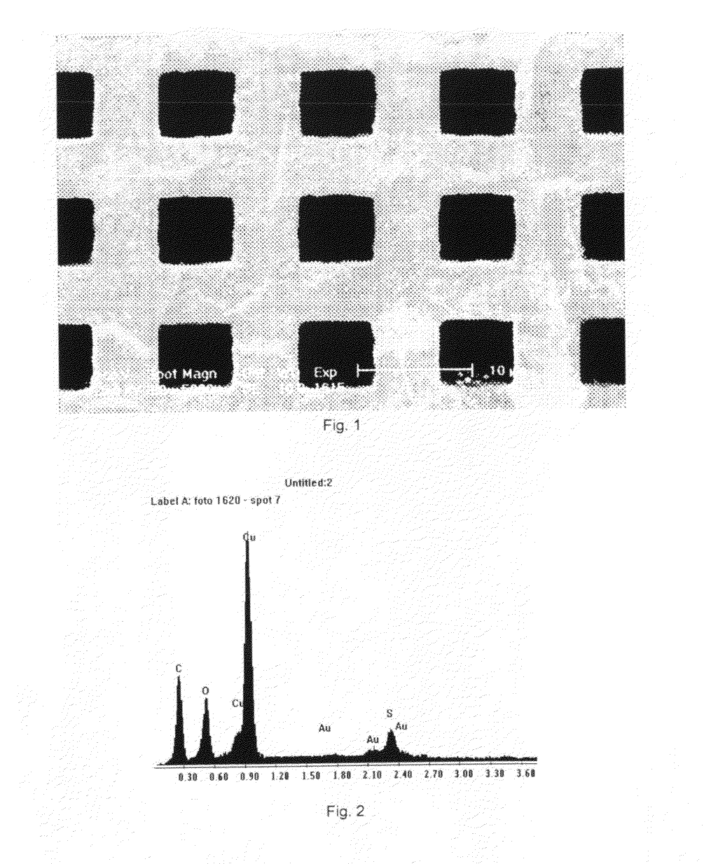

Copper was deposited in high vacuum on a Au grid with pore sizes of 7.5 micron wide. The plating bath was 1-butyl-3-methylimidazolium bis(trifluoromethylsulfonyl)imide in which 0.1 mol dm⁻³ of copper bis(trifluoromethylsulfonyl)imide was dissolved. Before use, the plating solution was placed inside a vacuum chamber and the pressure was reduced to 2 10⁻⁶ mbar. Next, the solution was placed inside the e-SEM and the pressure was reduced to 10⁻⁴ mbar. During the electrodeposition process, the pressure dropped further to 2 10⁻⁶ mbar. The plating solution was held in a copper crucible that was heated to 90° C. This crucible also served as counter electrode, no reference electrode was used. After a few hours, a deposit of about 1 micron thick was formed on the Au-grid. The deposit was smooth and adhered firmly to the substrate (FIG. 1). The EDX analysis after placing the grid in acetone overnight to dissolve the ionic liquid shows a clear copper peak and the Au substrate is totally screened by the deposit, even at 25 kV (FIG. 2).

### EXAMPLE 2

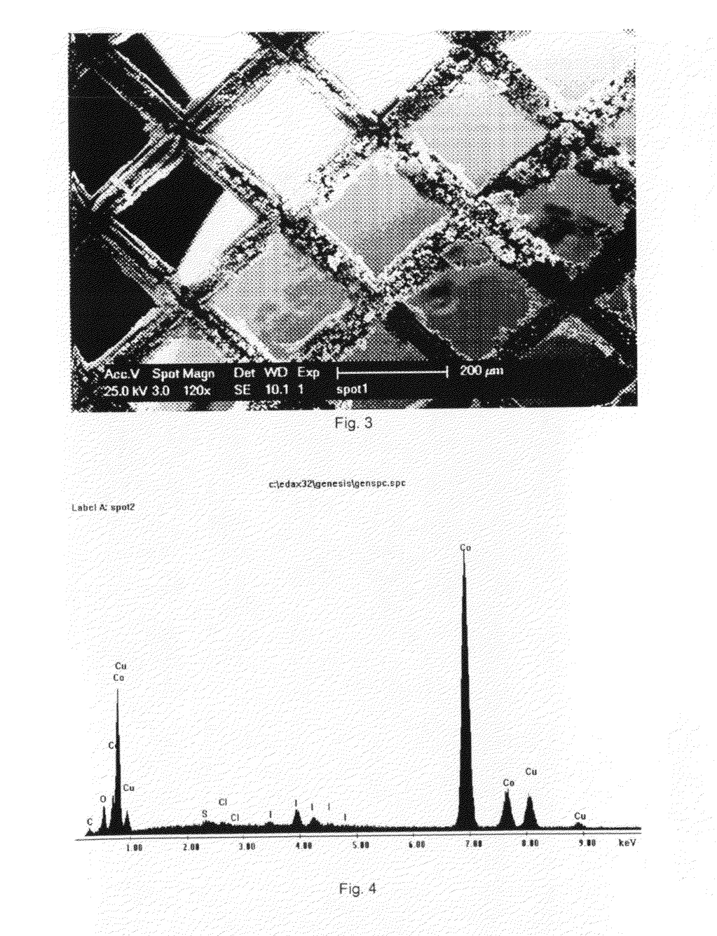

Deposits of cobalt were made in low vacuum using the e-SEM. The pressure was 3 torr of N₂ and the acceleration voltage 25 kV. The substrate was a copper grid, whose pores are 200 micron wide. The solution that was used was 1-butyl-1-methylpyrrolidinium bis(trifluoromethylsulfonyl)imide in which 0.1 mol dm⁻³ of anhydrous Col₂ was dissolved. Before use, this solution was dried at 120° C. under reduced pressure. The solution was contained in a copper crucible, in which a layer of cobalt had been electrodeposited from an aqueous CoCl₂ bath, and this crucible served as counter electrode. It was heated by a Peltier element to about 90° C. A voltage of −3.00 V was hold between the working and counter electrode for about 2 hours. No reference electrode was used. After the deposition, dendritic cobalt deposits could be seen on the copper substrate (FIG. 3). The EDX analysis after placing the grid in acetone overnight to dissolve the ionic liquid and any adhering resin shows a very distinct cobalt peak (FIG. 4).

### EXAMPLE 3

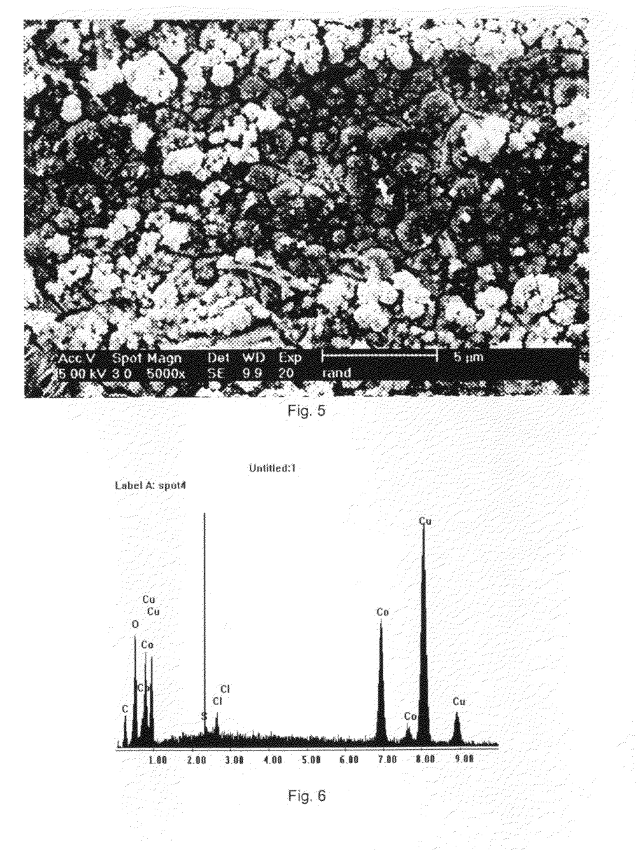

Cobalt was deposited in high vacuum on a Cu grid with 200 micron wide pores. The plating bath was [BMP][Tf₂N] in which 0.2 mol dm⁻³ Co(Tf₂N)₂ was dissolved. Before use, the plating solution was placed inside a vacuum chamber and the pressure was reduced to 2 10⁻⁶ mbar. Next, the solution was placed inside the e-SEM and the pressure was reduced to 1 10⁻⁴ mbar. During the electrodeposition process, the pressure dropped further to 5.4 10⁻⁶ mbar. The plating solution was held in a copper crucible that was heated to 90° C. This crucible also served as counter electrode, no reference electrode was used. A voltage of 2 V was applied between the anode and cathode. After 90 minutes, a deposit had formed on the Cu-grid (FIG. 5). The EDX analysis after placing the grid in acetone overnight to dissolve the ionic liquid shows clear cobalt peaks (FIG. 6).

### EXAMPLE 4

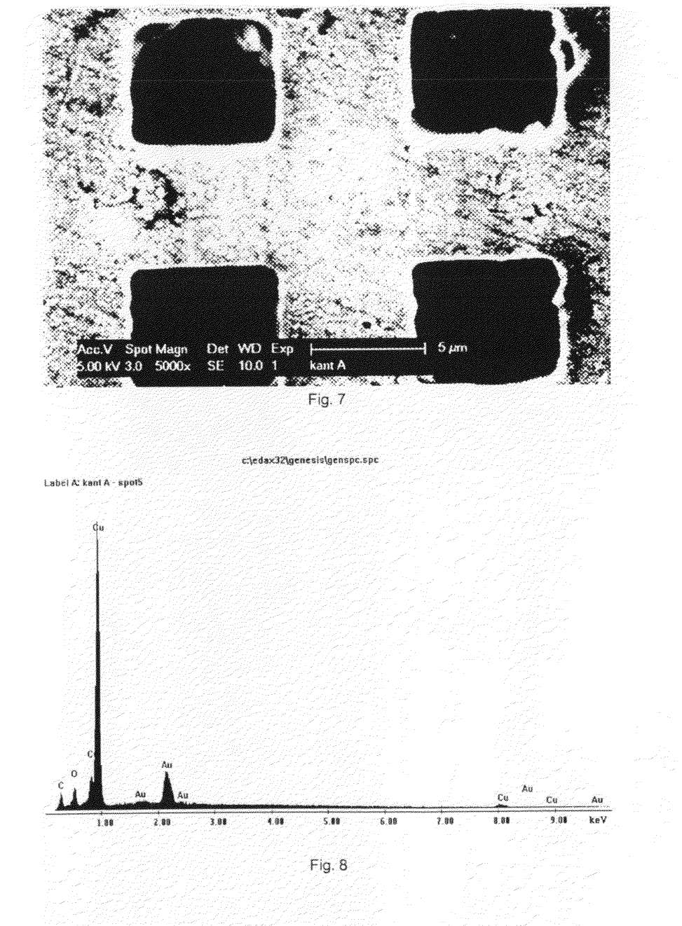

Copper was deposited in high vacuum on a Au grid with pore sizes of 7.5 micron wide. The plating bath was 1-butyl-1-methylpyrrolidinium bis(trifluoromethylsulfonyl)imide in which 0.2 mol dm⁻³ of copper bis(trifluoromethylsulfonyl)imide was dissolved. Before use, the plating solution was placed inside a vacuum chamber and the pressure was reduced to 2 10⁻⁶ mbar. Next, the solution was placed inside the e-SEM and the pressure was reduced to 1 10⁻⁴ mbar. During the electrodeposition process, the pressure dropped further to 2 10⁻⁶ mbar. The plating solution was held in a copper crucible that was heated to 90° C. This crucible also served as counter electrode, no reference electrode was used. A voltage of 2 V was applied between the anode and cathode. After 3 hours, a smooth deposit had formed (FIG. 7). The EDX analysis after placing the grid in acetone overnight to dissolve the ionic liquid shows a clear copper peak (FIG. 8).

### EXAMPLE 5

The substrate is transferred to a transfer module (in which the pressure is of the order of 10⁻⁵ Pa) through a load-lock. From the transfer module, the substrate is transferred to a deposition chamber where the deposition of the Tantalum layer takes place (e.g. by means of Physical Vapor Deposition (PVD) at a base pressure of the order of 10⁻⁸ Pa). After the deposition of the Tantalum layer, the substrate is transferred back to the transfer module and subsequently transferred to a second deposition chamber (pressure below 10⁻⁴ Pa) where the substrate is brought into contact with the ionic liquid and the deposition of metallic or semiconducting species from the ionic liquid onto the substrate takes place. Prior to this deposition process, the ionic liquid has been subjected to a vacuum step (with a pressure below 10⁻⁴ Pa).

### REFERENCES

U.S. Pat. No. 4,624,753, Method for electrodepositing of metals, G. E. MacMannis III et al.
U.S. Pat. No. 6,573,405, Ionic liquids, from Abbott et al.
U.S. Pat. No. 7,196,221, Ionic liquids and their use, from Abbott et al.
WO2006/053362 A2, Method for depositing layers from ionic liquids, from Schottenberger Herwig et al.,
WO2006/061081 A2, Electrochemical deposition of tantalum and/or copper in ionic liquids, from Welz-Biermann et al.
WO2006/074523 A1, Recovery of metals, from Houchin et al.
WO2007039035, Electrochemical deposition of selenium in ionic liquids, Welz-Biermann and Endres Frank.
CN1884622, Metal cobalt electrodeposition method by ion liquid, Yang Peixia An
The distillation and volatility of ionic liquids, Nature, vol. 439, 16 Feb. 2006, 831-834, M. J. Eerie, J. M. S. S. Esperanga, M. A. Gilea, J. N. Canongia Lopez, L. P. N. Rebelo, J. W. Magee, K. R. Seddon and J. A. Widegren
Vapourisation of ionic liquids, J. P. Armstrong, C. Hurst, R. G. Jones, P. Licence, K. R. J. Lovelock, C. J. Satterley and I. J. Villar-Garcia, Phys. Chem. Chem. Phys, vol. 9, 982-990 (2007)
Relative volatilities of ionic liquids by vacuum distillation of mixtures, J. A. Widgren, Y. M. Wang, W. A. Henderson and J. W. Magee, J. Phys. Chem. B, published on the web Jul. 7, 2007
Vapor pressure and thermal stability of ionic liquid 1-butyl-3-methylimidazolium bis(trifluoromethylsulfonyl)amide, Y. U. Paulechka, Dz. H. Zaitsau, G. J. Kabo and A. A. Strechan, Thermochimica Acta, Vol. 439, pp. 158-160 (2005)
Experimental vapor pressures of 1-alkyl-3-methylimidazolium bis(trifluoromethylsulfonyl)imides and a correlation scheme for estimation of vaporization enthalpies of ionic liquids, D. H. Zaitsau, G. J. Kabo, A. A. Strechan, Y. U. Paulechka, A. Tschersich, S. P. Verevkin and A. Heintz, J. Phys. Chem. A, vol 110, pp. 7303-7306 (2006).
Ionic liquids in vacuo: analysis of liquid surfaces using ultra-high-vacuum techniques, E. F. Smith, F. J. M. Rutten, I. J. Villar-Garcia, D. Briggs and P. Licence, Langmuir, vol. 22, pp. 9386-9392 (2006)
Ionic liquids in vacuo; solution-phase X-ray photoelectron spectroscopy, E. F. Smith, I. J. Villar-Garcia, D. Briggs and P. Licence).
Deposition of metal films on an ionic liquid as a basis for a lunar telescope, E. F. Borra, O, Seddiki, R. Angel, D. Eisenstein, P. Hickson, K. R. Seddon and S. P. Worden, Nature, vol. 447, pp. 979-981, 21 Jun. 2007
Electrochemical aspects of ionic liquids, H. Ohno (editor), Wiley Interscience, Tokyo (2005) and references therein
El Abedin, S Z; Endres, F, Electrodeposition of metals and semiconductors in air- and water-stable ionic liquids, CHEMPHYSCHEM, 7 (1): 58-61 Jan. 16, 2006
Abbott, A P; Capper, G; Swain, B G; et al., Electropolishing of stainless steel in an ionic liquid, TRANSACTIONS OF THE INSTITUTE OF METAL FINISHING, 83 (1): 51-53 January 2005
Buzzeo, M C; Evans, R G; Compton, R G, Non-haloaluminate room-temperature ionic liquids in electrochemistry—A review, CHEMPHYSCHEM, 5 (8): 1106-1120 Aug. 20, 2004
Endres, F, Ionic liquids: Promising solvents for electrochemistry, ZEITSCHRIFT FUR PHYSIKALISCHE CHEMIE-INTERNATIONAL JOURNAL OF RESEARCH IN PHYSICAL CHEMISTRY & CHEMICAL PHYSICS, 218 (2): 255-283 2004

1. A method for depositing metallic or semiconducting elements or combinations thereof on a substrate from an ionic liquid from which oxygen and water are depleted by exposing the ionic liquid to an atmospheric pressure lower than 10⁻² Pa prior to the deposition and wherein the atmospheric pressure is maintained below 10⁻² Pa during at least the initial phase of the deposition.

2. The method according to claim 1 wherein the substrate is transferred into the ionic liquid after the ionic liquid is depleted from oxygen and water by exposing the ionic liquid to a pressure below 10⁻² Pa.

3. The method according to claim 1 wherein the ionic liquid has a vapour pressure at room temperature below 10⁻⁴ Pa.

4. The method according to claim 1 wherein the atmospheric pressure prior to deposition and/or during the deposition is lower than 10⁻⁴ Pa.

5. The method according to claim 1 wherein the metallic or semiconducting elements or the combinations thereof are deposited by electrodeposition.

6. The method according to claim 1 wherein the metallic or semiconducting elements or the combinations thereof are deposited by electroless deposition.

7. The method according to claim 1 wherein copper is deposited on a tantalum or tantalum nitride coated substrate.

8. The method according to claim 7 wherein the tantalum or tantalum nitrate coated substrate is obtained by sputtering tantalum or tantalum nitride.

9. The method according to claim 8 wherein the tantalum or tantalum nitride coated substrate is protected from exposure to oxidising agents prior to and during the transfer to the ionic liquid.

10. A material obtained through the use of the method according to claim 1.

11. The method according to claim 2 wherein the ionic liquid has a vapour pressure at room temperature below 10⁻⁴ Pa.

12. The method according to claim 2 wherein the atmospheric pressure prior to deposition and/or during the deposition is lower than 10⁻⁴ Pa.

13. The method according to claim 3 wherein the atmospheric pressure prior to deposition and/or during the deposition is lower than 10⁻⁴ Pa.
